(19) United States
(12) Patent Application Publication
(10) Pub. No.: US 2007/0207344 A1
(43) Pub. Date: Sep. 6, 2007

(54) Organic Electroluminescent Device and Display Apparatus Using the Same

(75) Inventors: Jun Kamatani, Tokyo (JP); Shinjiro Okada, Kanagawa-ken (JP); Takao Takiguchi, Tokyo (JP); Akira Tsuboyama, Tokyo (JP); Satoshi Igawa, Kanagawa-ken (JP); Manabu Furugori, Tokyo (JP)

Correspondence Address: FITZPATRICK CELLA HARPER & SCINTO, 30 ROCKEFELLER PLAZA, NEW YORK, NY, 10112, US

(73) Assignee: Canon Kabushiki Kaisha, Tokyo (JP)

(21) Appl. No.: 11/578,068

(22) PCT Filed: Oct. 12, 2005
(86) PCT No.: PCT/JP05/19155

§ 371 Date: Oct. 12, 2006

(30) Foreign Application Priority Data
Oct. 14, 2004 (JP) 2004-299928

(51) Int. Cl. H01L 51/54

(52) U.S. Cl. 428/690; 428/917; 313/504; 257/E51.044

(57) ABSTRACT

The present invention provides an organic electroluminescent device using a novel light-emitting material. The organic electroluminescent device of the present invention is formed by using an organic compound having an emission wavelength in a single-body state shorter than that in a solution as a light-emitting material, doping the light-emitting material with a conductive material to form a light-emitting layer in such a manner that the content of the conductive material in the light-emitting layer is lower than that of the light-emitting material therein, and interposing the light-emitting layer between electrodes.

### TECHNICAL FIELD

The present invention relates to an organic electroluminescent device to be used for a flat panel display apparatus and a display apparatus using the same.

### BACKGROUND ART

Applied research has been vigorously made on an organic electroluminescent (EL) device as a high-speed responsive and high-efficiency light-emitting device. FIGS. 1A and 1B each show the basic constitution of the device (see, for example, Macromol. Symp. 125, 1 to 48 (1997)). In FIGS. 1A and 1B, reference numeral 11 denotes a metal electrode; 12, a light-emitting layer; 13, a hole-transporting layer; 14, a transparent electrode; 15, a transparent substrate; and 16, an electron-transporting layer.

As shown in FIGS. 1A and 1B, the organic EL device is generally constituted by a stacked body having a plurality of organic compound layers interposed between the transparent electrode 14 and the metal electrode 11 on the transparent substrate 15.

In FIG. 1A, the organic compound layers are composed of the light-emitting layer 12 and the hole-transporting layer 13. For example, ITO having a large work function is used for the transparent electrode 14 to provide good property of injecting a hole from the transparent electrode 14 to the hole-transporting layer 13. A metal material having a small work function such as aluminum, magnesium, or an alloy thereof is used for the metal electrode 11 to provide good property of injecting electrons to the organic compound layers. Those electrodes each have a thickness in the range of 50 to 200 nm.

For example, an aluminum-quinolinol complex (typified by tris(8-quinolalito)aluminum (Alq₃)) having electron-transporting and light-emitting properties is used for the light-emitting layer 12. In addition, a material having electron-donative property such as a triphenyl diamine derivative (typified by bis[N-(1-naphthyl)-N-phenyl]benzidine (α-NPD)) is used for the hole-transporting layer 13.

The organic EL device having the above-described constitution shows rectifying property. When an electric field is applied in such a manner that the metal electrode 11 serves as a cathode and the transparent electrode 14 servers as an anode, an electron is injected from the metal electrode 11 to the light-emitting layer 12, and a hole is injected from the transparent electrode 14 to the light-emitting layer.

The injected hole and electron recombine in the light-emitting layer 12 to produce an exciton, whereby light is emitted. At this time, the hole-transporting layer 13 serves as an electron blocking layer. As a result, efficiency of recombination at the interface between the light-emitting layer 12 and the hole-transporting layer 13 increases, and hence emission efficiency increases.

In FIG. 1B, the electron-transporting layer 16 is arranged between the metal electrode 11 and the light-emitting layer 12 in FIG. 1A. Light emission and electron/hole transport are separated to provide a more effective carrier blocking constitution, whereby light emission can be performed efficiently. For example, an oxadiazole derivative can be used for the electron-transporting layer 16.

The organic EL device has been attracting attention because of its potential to serve as a light-emitting device constituting a flat panel display apparatus. Therefore, the development of a light-emitting material as a main member for the device has been urgently necessary in order to cope with a wider variety of requests.

### DISCLOSURE OF THE INVENTION

An object of the present invention is to provide a novel organic EL device using a novel light-emitting material, to thereby increase the degree of freedom of selection in, for example, the applications and production process of the device and a member except the light-emitting material.

According to one aspect of the present invention, there is provided an organic electroluminescent device including: a pair of electrodes, and at least one organic compound layer including a light-emitting layer, interposed between the pair of electrodes, wherein the light-emitting layer in the organic compound layer is composed of at least two kinds of compounds, and among the compounds, a compound having the highest concentration is a light-emitting material, which is an organic compound having an emission wavelength of a single body in a solid state shorter than that of the single body in a solution.

According to another aspect of the present invention, there is provided a display apparatus using the above-described organic electroluminescent device.

According to the present invention, there are provided an organic electroluminescent device using a novel light-emitting material that has not been present heretofore, and a display apparatus using the device. Therefore, the degree of freedom of selection in the constitution and production of the device or of the display apparatus increases.

### BRIEF DESCRIPTION OF THE DRAWINGS

FIG. 1A and FIG. 1B are schematic sectional views each showing an example of the constitution of an organic EL device of the present invention.

FIG. 2 is a schematic plan view showing another example of the constitution of the organic EL device of the present invention.

FIG. 3 is a schematic plan view showing the constitution of an active matrix substrate using the organic EL device of the present invention.

FIG. 4 is a view showing an equivalent circuit of a pixel circuit of FIG. 3.

FIG. 5 shows emission wavelength spectra of an organic compound used in Example 1 and Comparative Example 1.

FIG. 6 is a graph showing voltage-current characteristics of organic EL devices of Example 1 and Comparative Example 1.

FIG. 7 is a graph showing current-emission luminance characteristics of the organic EL devices of Example 1 and Comparative Example 1.

FIG. 8 is a graph showing voltage-emission luminance characteristics of the organic EL devices of Example 1 and Comparative Example 1.

FIG. 9 is a graph showing emission luminance-emission efficiency characteristics of the organic EL devices of Example 1 and Comparative Example 1.

FIG. 10 shows emission wavelength spectra of the organic EL devices of Example 1 and Comparative Example 1.

FIG. 11 is a schematic view showing a stacked constitution in Example 2.

FIG. 12 shows a drive waveform used in Example 2.

### BEST MODE FOR CARRYING OUT THE INVENTION

The organic electroluminescent device (hereinafter, referred to as the “organic EL device”) of the present invention has the same basic constitution as that shown in each of FIGS. 1A and 1B, and is formed in the same manner as in a conventional device except for the light-emitting layer 12.

First, reference numerals in all the figures will be described.

Reference numeral 11 denotes the metal electrode; 12, the light-emitting layer; 13, the hole-transporting layer; 14, the transparent electrode; 15, the transparent substrate; and 16, the electron-transporting layer.

Reference numeral 20 denotes a pixel circuit; 21, a scanning signal driver; 22, an information signal driver; 23, a current source; 25, a gate scanning line; 26, an information line; 27, a current supply line; each of 31 and 32, a TFT; 33, a capacitor; 34, an organic EL device; and 35, an anode.

Reference numeral 40 denotes a glass substrate; 41, a source region; 42, a drain region; 43, a channel region; 44, a p-Si layer; 45, a gate electrode; 46, a drain electrode; 47, a source electrode; 48, a gate insulating film; and each of 49, 52, and 53, an insulating layer.

Reference numeral 50 denotes an ITO electrode; 51, an organic compound layer; 52, a cathode layer; 111, a glass substrate; 112, a transparent electrode; 113, an organic compound layer; and 114, a metal electrode.

A light-emitting material used for a conventional organic EL device has an emission wavelength of a single body in a solid state equal to or longer than that of the single body in a solution, or the single body in the solution does not emit light at all. In contrast, an organic compound to be used as a light-emitting material for the EL device of the present invention has an emission wavelength of a single body in a solid state shorter than that of the single body in a solution. The organic compound is expected to emit light owing to a certain intermolecular interaction.

The term “solid state” as used herein refers to a crystalline state or an amorphous state. When an emission wavelength is measured in a solution, any one of toluene, chloroform, chlorobenzene, methyl THF, THF, acetonitrile, methanol, ethanol, water, DMF, and acetone is used as the solution. An emission wavelength in a solution is an emission wavelength measured by dissolving a material into the solution at a concentration of 10⁻⁵ mol/l or less. To utilize light emission of such organic compound in a solid state, the organic compound must be used at a high concentration close to that of a single body in a solid state rather than at a low concentration as in the case of a solution. To be specific, a light-emitting layer is desirably mixed with a light-emitting material at a concentration of 50% or more. However, when the light-emitting material is used at a concentration of 100%, a current amount reduces because of the conductivity and charge balance of the light-emitting material. To avoid this problem, the light-emitting layer is doped with a conductive material. By doing so, light emission can be performed with high efficiency. That is, the light-emitting material can be used at a high concentration in the light-emitting layer while its emission wavelength in a solid state is maintained.

In the present invention, the light-emitting layer is composed of at least two kinds of compounds. among the compounds, an organic compound to serve as a light-emitting material is added at the highest concentration to the light-emitting layer. The concentration of the light-emitting material in the light-emitting layer is preferably 50% or more, or more preferably 70% or more, and less than 100%. The concentration as used herein is represented in a mass % unit. In addition, a compound to be mixed into the light-emitting layer is used as a dopant not to suppress concentration quenching but to transport a carrier. In the present invention, the device having high efficiency can be produced by controlling a concentration ratio between the light-emitting material and the dopant in the light-emitting layer. That is, when spectral molecules are adjacent to each other, a light emission state changes. As a result, the device having an optimum charge balance while nearly maintaining its emission wavelength can be produced without any consideration for concentration quenching as a phenomenon in which emission efficiency reduces. Therefore, the device having high efficiency can be produced.

In view of the foregoing, the organic EL device of the present invention is suitable for a light-emitting device, and a good display apparatus can be constituted by using the organic EL device.

In actuality, the organic EL device of the present invention has been found to show high efficiency in an energization test.

The organic EL device of the present invention uses an organic compound having an emission wavelength in a solid state shorter than that in a solution state as a light-emitting material. Specifically, the organic compound is preferably a metal complex. More specifically, a metal complex having a central metal which is Cu, Re, Ru, W, Ag or Au is preferably used. Of those, a phosphorescent metal complex is preferable. Examples of the organic compound are shown the following Tables 1 and 2. Structural formulae shown by symbols in the tables are specifically shown in Chemical formulae 1 and 2. “Ph” in the tables represents a phenyl group, provided that those examples show only representative examples, and organic compounds that can be used in the present invention are not limited to those examples. In addition, the organic EL device of the present invention is preferably an electroluminescent device in which a light-emitting layer containing these organic compounds is interposed between two electrodes opposed to each other, and emits light when a voltage is applied between the electrodes.

TABLE 1

| | | L or | L′ or | | | | | | | |
|---|---|---|---|---|---|---|---|---|---|---|
| No. | Compound | L-L | L′-L′ | L″ | R₁ | R₁′ | R₁″ | R₂ | R₂′ | X |
| 1 | 1 | A | N | — | H | — | — | H | — | — |
| 2 | 1 | A | P | — | CH₃ | — | — | CH₃ | — | — |
| 3 | 1 | A | S | — | H | H | — | CH₃ | H | — |
| 4 | 1 | A | S | — | CH₃ | CF₃ | — | CH₃ | CF₃ | — |
| 5 | 1 | B | S | — | H | H | — | H | H | — |
| 6 | 1 | B | S | — | CH₃ | CF₃ | — | H | CF₃ | — |
| 7 | 1 | B | S | — | H | CF₃ | — | Ph | CF₃ | — |
| 8 | 1 | C | S | — | H | H | — | — | H | — |
| 9 | 1 | D | S | — | H | CF₃ | — | — | H | — |
| 10 | 1 | E | S | — | C₂H₅ | CF₃ | — | — | CF₃ | — |
| 11 | 1 | E | S | — | C₆H₁₃ | Ph | — | — | H | — |
| 12 | 1 | E | Q | — | CH(CH₃)₂ | CF₃ | — | — | H | — |
| 13 | 2 | A | — | — | H | — | — | CH₃ | — | U |
| 14 | 2 | B | — | — | H | — | — | F | — | U |
| 15 | 2 | B | — | — | H | — | — | H | — | U |
| 16 | 2 | C | — | — | H | — | — | — | — | U |
| 17 | 2 | C | — | — | CH₃ | — | — | — | — | V |
| 18 | 2 | D | — | — | H | — | — | — | — | U |
| 19 | 2 | E | — | — | C₂H₅ | — | — | — | — | U |
| 20 | 3 | M | — | — | — | — | — | — | — | — |
| 21 | 4 | N | — | — | — | — | — | — | — | U |
| 22 | 4 | O | — | — | — | — | — | — | — | U |
| 23 | 4 | P | — | — | — | — | — | — | — | X |
| 24 | 5 | N | — | — | — | — | — | — | — | U |
| 25 | 5 | Q | — | — | — | — | — | — | — | U |
| 26 | 5 | R | — | — | — | — | — | — | — | U |
| 27 | 6 | A | S | N | H | H | — | CH₃ | H | — |
| 28 | 6 | A | S | T | H | CH₃ | Ph | H | CH₃ | — |
| 29 | 6 | B | S | N | H | CH₃ | — | H | CF₃ | — |
| 30 | 6 | B | S | T | H | CH₃ | Ph | CH₃ | H | — |
| 31 | 6 | C | S | T | H | H | OC₂H₅ | — | H | — |
| 32 | 6 | D | S | T | H | CF₃ | OC(CH₃) | — | CF₃ | — |
| 33 | 6 | E | S | N | C₂H₅ | CF₃ | — | — | CF₃ | — |
| 34 | 6 | E | S | T | Ph | CF₃ | Ph | — | CF₃ | — |
| 35 | 7 | A | J | — | CH(CH₃)₂ | — | — | — | — | — |
| 36 | 7 | B | K | — | CH₃ | — | — | H | — | — |
| 37 | 7 | B | L | — | CH(CH₃)₂ | — | — | H | — | — |
| 38 | 7 | C | J | — | H | — | — | H | — | — |
| 39 | 7 | C | K | — | CH₃ | — | — | — | — | — |
| 40 | 7 | C | L | — | CH₃ | — | — | — | — | — |
| 41 | 7 | D | J | — | CH₃ | — | — | — | — | — |
| 42 | 7 | D | L | — | H | — | — | — | — | — |
| 43 | 7 | E | K | — | C₂H₅ | — | — | — | — | — |
| 44 | 7 | E | L | — | C₂H₅ | — | — | — | — | — |
| 45 | 7 | F | J | — | H | — | — | — | — | — |
| 46 | 7 | F | L | — | H | — | — | — | — | — |
| 47 | 7 | G | J | — | — | — | — | — | — | — |
| 48 | 7 | H | J | — | CH₃ | — | — | — | — | — |
| 49 | 7 | H | L | — | H | — | — | — | — | — |
| 50 | 7 | I | J | — | — | — | — | — | — | — |
| 51 | 7 | I | L | — | — | — | — | — | — | — |
| 52 | 8 | J | T | — | — | — | Ph | — | — | — |
| 53 | 8 | J | N | — | — | — | — | — | — | — |
| 54 | 8 | K | T | — | — | — | Ph | — | — | — |
| 55 | 8 | K | T | — | — | — | OC₂H₅ | — | — | — |
| 56 | 8 | L | T | — | — | — | Ph | — | — | — |
| 57 | 8 | L | T | — | — | — | OC₂H₅ | — | — | — |
| 58 | 8 | L | T | — | — | — | C(CH₃)₃ | — | — | — |
| 59 | 9 | A | T | X | CH₃ | — | Ph | H | — | — |
| 60 | 9 | A | N | X | CH(CH₃)₂ | — | — | CH₃ | — | — |

TABLE 2

| | | L or | L′ or | | | | | | | |
|---|---|---|---|---|---|---|---|---|---|---|
| No. | Compound | L-L | L′-L′ | L″ | R₁ | R₁′ | R₁″ | R₂ | R₂′ | X |
| 61 | 9 | A | T | X | CH(CH₃)₂ | — | Ph | H | — | — |
| 62 | 9 | A | T | Y | CH(CH₃)₂ | — | Ph | H | — | — |
| 63 | 9 | B | T | X | CH₃ | H | Ph | H | — | — |
| 64 | 9 | B | N | X | CH(CH₃)₂ | H | — | H | — | — |
| 65 | 9 | B | T | X | CH(CH₃)₂ | Ph | Ph | CH₃ | — | — |
| 66 | 9 | C | T | X | CH₃ | — | Ph | — | — | — |
| 67 | 9 | C | T | Y | CH₃ | — | Ph | — | — | — |
| 68 | 9 | D | T | X | CH₃ | — | Ph | — | — | — |
| 69 | 9 | D | T | X | CH(CH₃)₂ | — | Ph | — | — | — |
| 70 | 9 | E | T | X | C₂H₅ | — | Ph | — | — | — |
| 71 | 9 | E | T | X | Ph | — | Ph | — | — | — |
| 72 | 9 | F | T | X | H | — | Ph | — | — | — |
| 73 | 9 | F | T | X | CH₃ | — | Ph | — | — | — |
| 74 | 9 | G | T | X | — | — | Ph | — | — | — |
| 75 | 9 | G | T | Y | — | — | C₂H₅ | — | — | — |
| 76 | 9 | H | T | X | H | — | Ph | — | — | — |
| 77 | 9 | H | T | X | CH₃ | — | Ph | — | — | — |
| 78 | 9 | I | T | X | — | — | Ph | — | — | — |
| 79 | 9 | I | T | X | — | — | Ph | — | — | — |
| 80 | 9 | I | T | Y | — | — | OC₂H₅ | — | — | — |
| 81 | 10 | N | — | — | — | — | — | — | — | X |
| 82 | 10 | O | — | — | — | — | — | — | — | X |
| 83 | 10 | P | — | — | — | — | — | — | — | X |
| 84 | 10 | Q | — | — | — | — | — | — | — | X |
| 85 | 10 | R | — | — | — | — | — | — | — | X |
| 86 | 10 | T | — | — | — | — | Ph | — | — | X |
| 87 | 10 | T | — | — | — | — | OC₂H₅ | — | — | X |
| 88 | 10 | T | — | — | — | — | Ph | — | — | Y |
| 89 | 11 | A | T | — | CH(CH₃)₂ | — | Ph | H | — | X |
| 90 | 11 | A | T | — | CH(CH₃)₂ | — | Ph | CH₃ | — | X |
| 91 | 11 | B | T | | CH(CH₃)₂ | — | Ph | H | — | X |
| 92 | 11 | B | P | — | CH(CH₃)₂ | — | — | H | — | X |
| 93 | 11 | D | T | — | CH₃ | — | Ph | — | — | X |
| 94 | 11 | E | T | — | C₂H₅ | — | Ph | — | — | X |
| 95 | 11 | F | T | — | CH₃ | — | Ph | — | — | X |
| 96 | 11 | H | T | — | CH₃ | — | Ph | — | — | X |
| 97 | 11 | I | T | — | — | — | Ph | — | — | X |
| 98 | 12 | A | — | — | CH₃ | — | — | H | — | X |
| 99 | 12 | A | — | — | CH(CH₃)₂ | — | — | CH₃ | — | X |
| 100 | 12 | B | — | — | CH(CH₃)₂ | — | — | H | — | X |
| 101 | 12 | B | — | — | CH(CH₃)₂ | — | CF₃ | H | — | X |
| 102 | 12 | C | — | — | CH₃ | — | — | — | — | X |
| 103 | 12 | C | — | — | CH(CH₃)₂ | — | — | — | — | X |
| 104 | 12 | D | — | — | H | — | — | — | — | X |
| 105 | 12 | D | — | — | CH₃ | — | — | — | — | X |
| 106 | 12 | E | — | — | C₂H₅ | — | — | — | — | X |
| 107 | 12 | E | | | Ph | — | — | — | — | X |
| 108 | 12 | F | — | — | H | — | — | — | — | X |
| 109 | 12 | F | — | — | CH₃ | — | — | — | — | X |
| 110 | 12 | G | — | — | — | — | — | — | — | X |
| 111 | 12 | G | — | — | — | — | — | — | — | X |
| 112 | 12 | H | — | — | H | — | — | — | — | X |
| 113 | 12 | H | — | — | CH₃ | — | — | — | — | X |
| 114 | 12 | I | — | — | — | — | — | — | — | X |

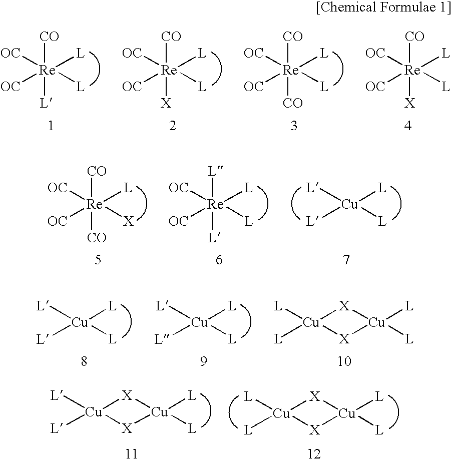

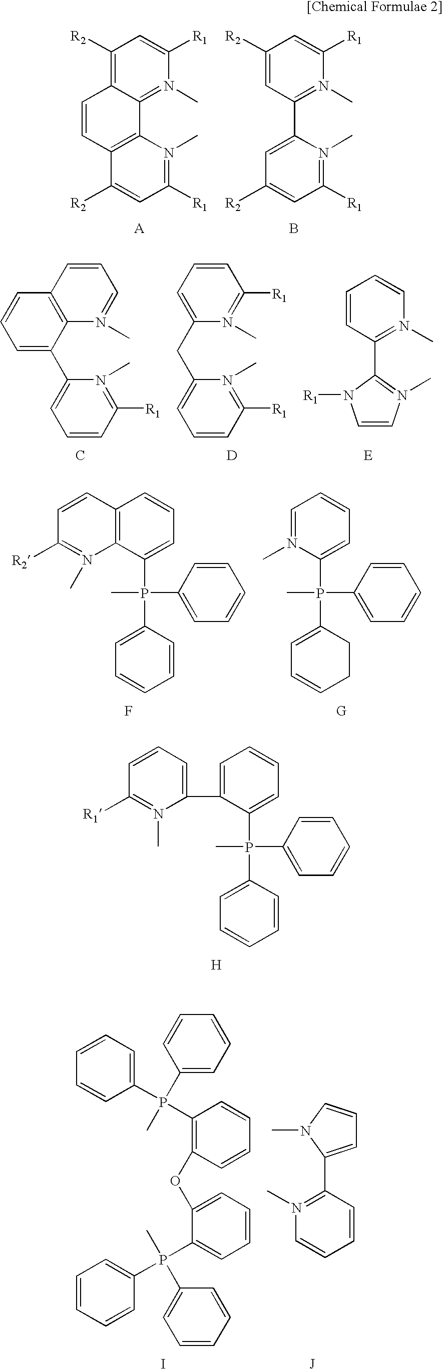

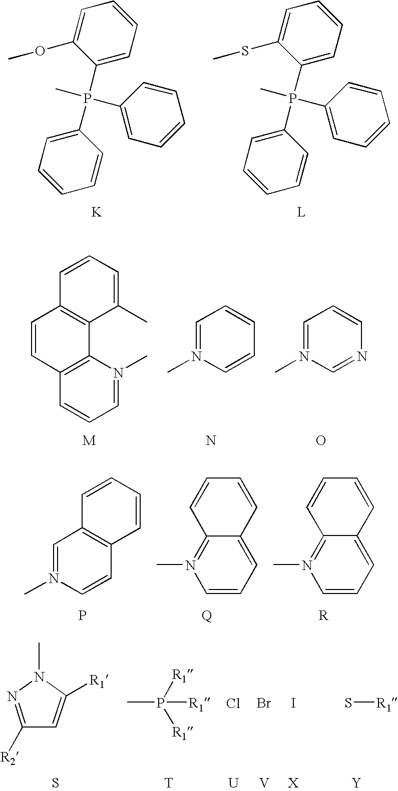

The organic EL device of the present invention is applicable to products requiring energy saving and high luminance. Potential applications of the device include: light sources for display apparatuses, lighting systems, and printers; and backlights for liquid crystal display apparatuses. A display apparatus using the device can be a flat panel display that achieves energy savings, high visibility, and a light weight. In addition, a laser light source portion of a laser beam printer that has been currently used vigorously can be replaced with the organic EL device of the present invention capable of serving as a light source for a printer. The devices that can be independently addressed are arranged in an array form, and a photosensitive drum is subjected to desired light exposure, whereby an image is formed. The use of the organic EL device of the present invention can significantly reduce the volume of an apparatus. The present invention is expected to have an energy saving effect on a lighting system or on a backlight.

When the organic EL device is applied to a display, the device is probably driven by means of a TFT drive circuit according to an active matrix system.

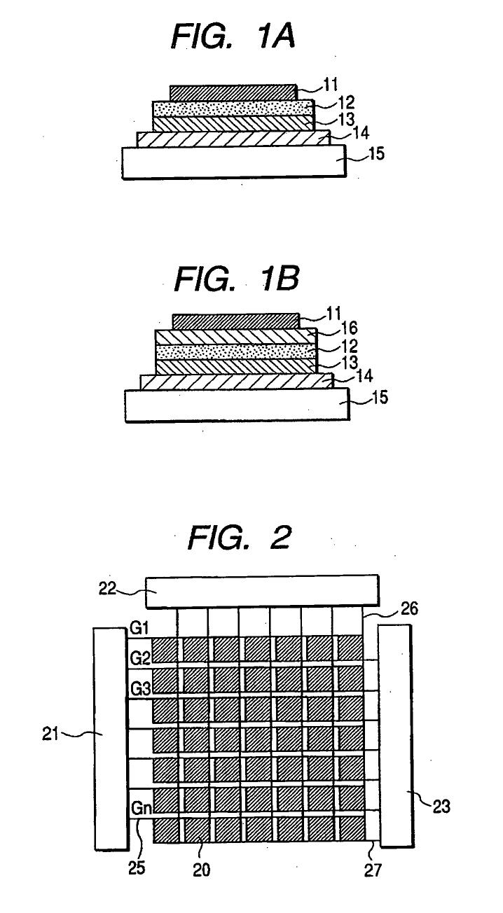

Hereinafter, an active matrix substrate when the organic EL device of the present invention is applied to a display apparatus according to an active matrix system will be described with reference to FIGS. 2 to 4.

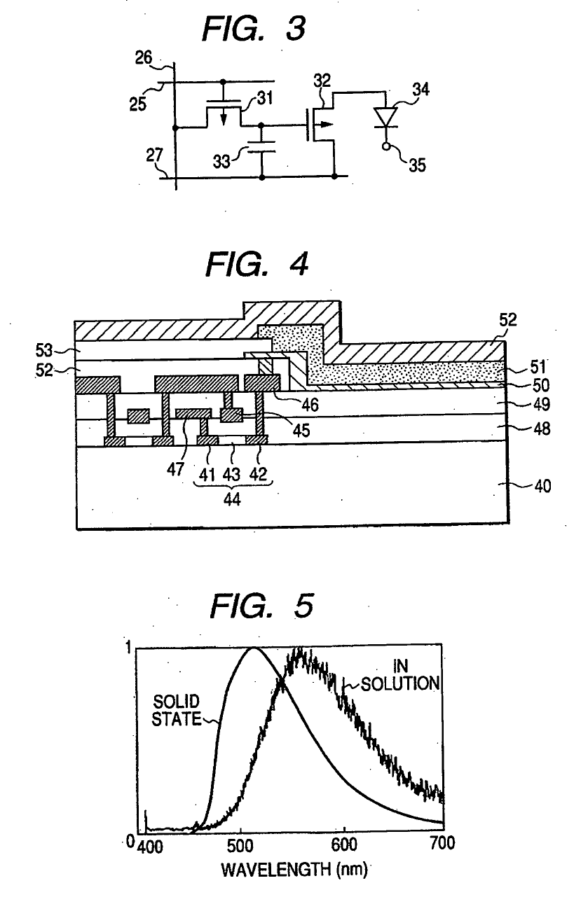

FIG. 2 is a plan view schematically showing the constitution of an active matrix substrate which has a plurality of organic EL devices of the present invention arranged thereon and which is equipped with drive means. Arranged on a panel are the pixel circuits 20, the scanning signal driver 21, the information signal driver 22, and the current source 23 each of which is connected to the gate scanning lines 25, the information lines 26, and the current supply lines 27. FIG. 3 shows an example of the constitution of the pixel circuit 20 arranged at an intersection of the gate scanning line 25 and the information line 26. The scanning signal driver 21 sequentially selects the gate scanning lines G1, G2, G3, . . . , and Gn. In synchronization with the selection, an image signal is applied from the information signal driver 22.

Next, the operation of the pixel circuit 20 will be described. In the pixel circuit 20, when a selection signal is applied to the gate scanning line 25, the TFT 31 is turned on to supply an image signal to the capacitor 33, whereby the gate potential of the TFT 32 is determined. The organic EL device 34 is supplied with a current from the current supply line 27 in accordance with the gate potential of the TFT 32. Since the gate potential of the TFT 32 is maintained in the capacitor 33 until the TFT 31 is scanned and selected for the next time, a current continues to flow through the organic EL device 34 until the next scan is performed. Thus, the device can be caused to emit light at all times during a one-frame period.

FIG. 4 is a schematically cross-sectional view showing the structure of the TFT to be used in this example. The p-Si layer 44 is provided on the glass substrate 40, and the respective regions of the channel 43, the drain 42 and the source 41 are doped with necessary impurities. The gate electrode 45 is provided thereon through the gate insulating film 48. In addition, the drain electrode 46 and the source electrode 47 to be connected to the drain region 42 and the source region 41 are formed. The insulating layers 49 and 52 and the ITO electrode 50 as a pixel electrode are stacked on those electrodes. The ITO electrode 50 and the drain electrode 46 are connected through a contact hole.

In the present invention, a switching element is not particularly limited, and a single crystal silicon substrate, an MIM element, an a-Si type element and the like can be easily applied as the switching element.

One or more organic compound layers 51, and the cathode layer 52 are sequentially stacked on the ITO electrode 50, whereby an organic EL display panel can be obtained. Driving a display panel using the organic EL device of the present invention allows an image with good quality to be stably displayed for a long time period.

Hereinafter, the present invention will be described specifically by way of examples.

### EXAMPLE 1 AND COMPARATIVE EXAMPLE 1

An organic EL device having three organic compound layers as shown in FIG. 1B was produced as follows. First, an ITO electrode (transparent electrode 14) having a thickness of 100 nm was patterned onto a glass substrate (transparent substrate 15) to have an opposing electrode area of 3 mm². The organic compound layers 1 to 3 and electrode layers 1 to 2 as described below were vacuum-deposited onto the ITO electrode and substrate in a vacuum chamber at 10⁻⁴ Pa by resistance heating to carry out continuous film formation. An organic EL device having the organic compound layer 2 not doped with CBP (4,4′-N,N′-dicarbazole-biphenyl) was also produced as Comparative Example 1.

Organic compound layer 1 (hole-transporting layer 13) (40 nm): TFB4

Organic compound layer 2 (light-emitting layer 12) (20 nm): Organic compound 4+CBP (mass ratio=70:30)

Organic compound layer 3 (electron-transporting layer 16) (50 nm): Bphen

Metal electrode layer 1 (1 nm): KF

Metal electrode layer 2 (100 nm): Al

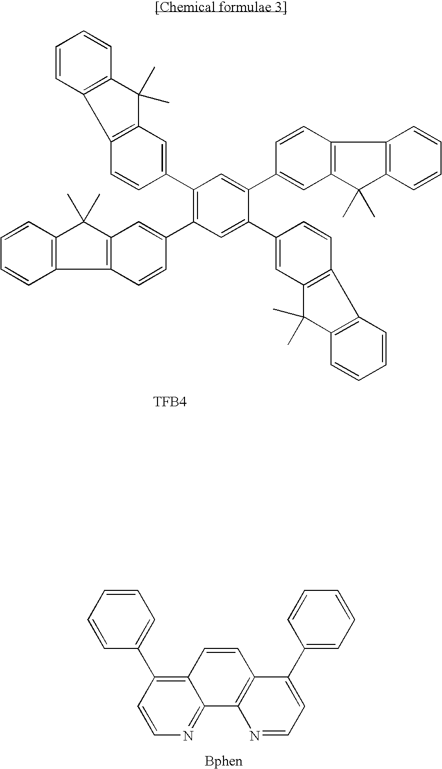

The organic compound 4 used in this example has emission wavelengths of 515 nm in a solid state and 561 nm in a toluene solution. FIG. 5 shows emission wavelength spectra of the respective states.

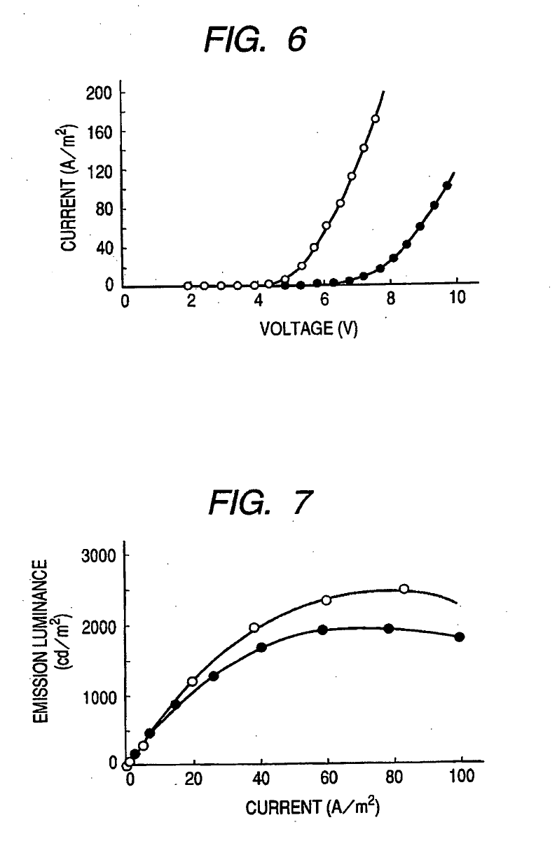

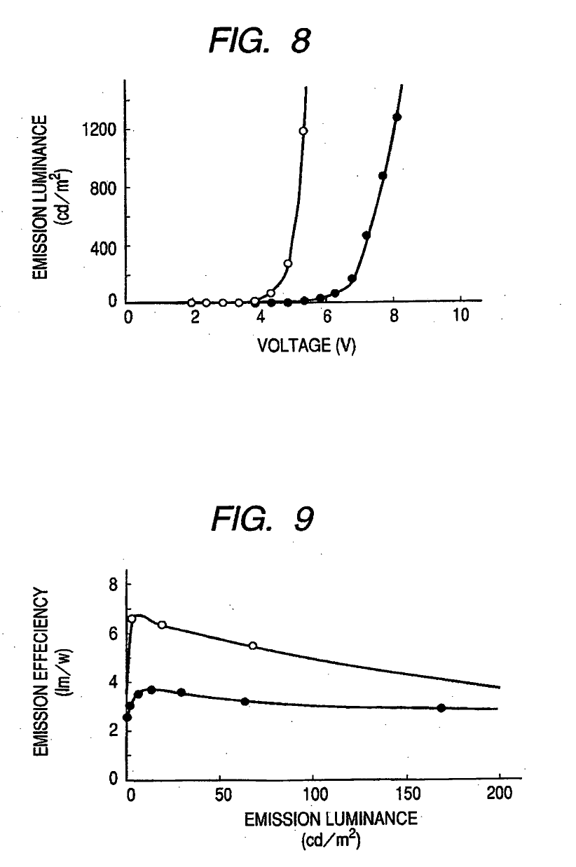

The voltage-current characteristics of the organic EL devices were measured by means of a microammeter 4140B manufactured by Hewlett-Packard Development Company, L.P., and the emission luminances thereof were measured by means of a BM7 manufactured by Topcon Corporation. FIG. 6 shows the voltage-current characteristics of the device of Example 1 (open circle “∘” in the figure) and the device of Comparative Example 1 (solid circle “●” in the figure). FIG. 7 shows current-emission luminance characteristics of the device of Example 1 (∘) and the device of Comparative Example 1 (●). FIG. 8 shows voltage-emission luminance characteristics of the device of Example 1 (∘) and the device of Comparative Example 1 (●). FIG. 9 shows emission luminance-emission efficiency characteristics of the device of Example 1 (∘) and the device of Comparative Example 1 (●). FIG. 10 shows emission wavelength spectra of the device of Example 1 (dashed line in the figure) and the device of Comparative Example 1 (line in the figure).

As a result, it was found that the addition of 30 mass % CBP increased emission efficiency while allowing an emission wavelength to remain nearly unchanged.

The result showed that an organic compound having an emission wavelength in a solid state shorter than that in a solution, which can emit light even at a concentration of 100% in a light-emitting layer, can increase its emission efficiency while nearly maintaining its emission wavelength when the compound is doped with a small amount of conductive material.

### EXAMPLE 2

An ITO film having a thickness of about 100 nm was formed as a transparent electrode (on an anode side) by sputtering on a glass substrate having 75 mm-long, 75 mm-wide and 1.1 mm-thick size. After that, the ITO film was patterned to form 100 lines of in a width ratio of line/space=100 μm/40 μm as simple matrix electrodes. Next, three organic compound layers were produced thereon under the same conditions as in Example 1.

Subsequently, 100 lines of metal electrodes were formed by vacuum deposition through a mask in a width ratio of line/space=100 μm/40 μm with a degree of vacuum of 2.66×10⁻³ Pa such that 100 lines of metal electrodes perpendicularly intersected 100 lines of the ITO electrodes. The metal electrodes of KF were formed in a thickness of 1 nm and subsequently metal electrodes of Al were formed in a thickness of 150 nm.

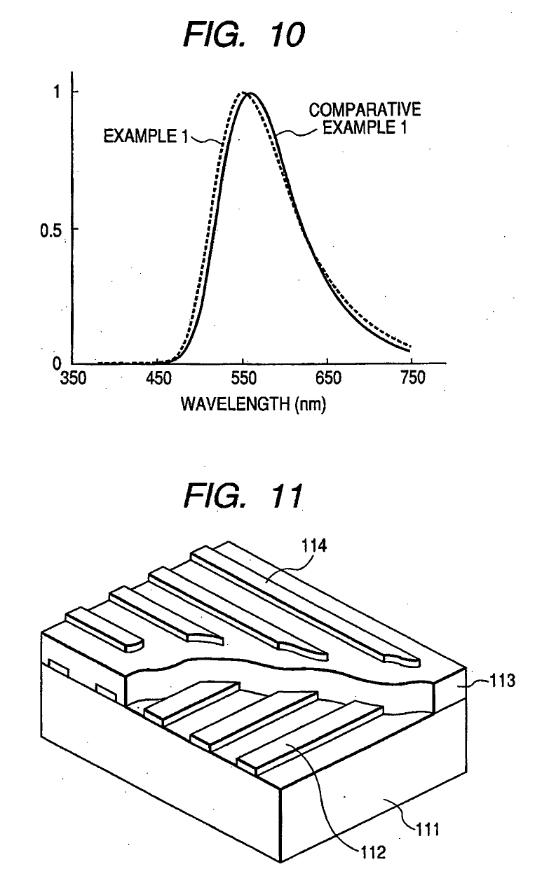

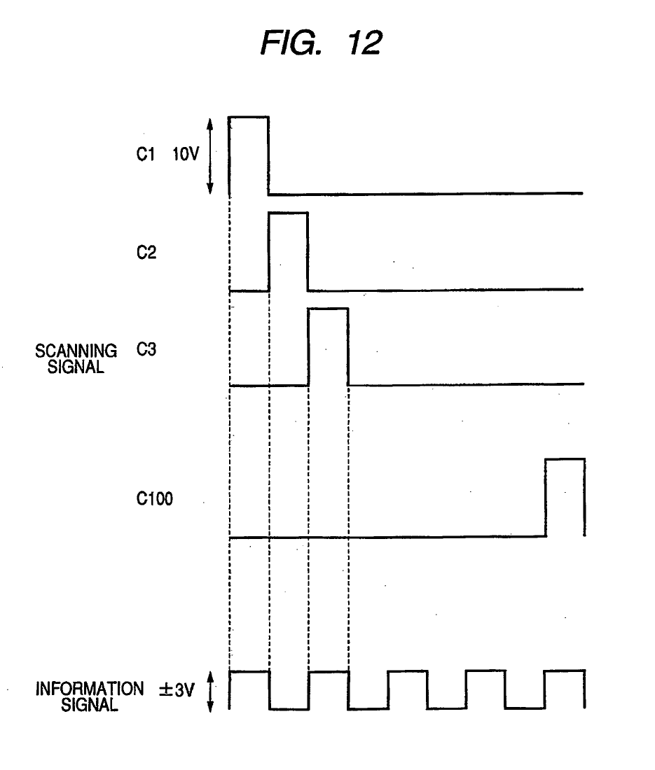

FIG. 11 schematically shows the constitution of the 100×100 simple matrix-type organic EL device. In the figure, reference numeral 111 denotes a glass substrate; 112, a transparent electrode; 113, a organic compound layer; and 114, a metal electrode. The device was subjected to simple matrix driving in a glove box filled with a nitrogen atmosphere in the range of 7 V to 13 V by means of a scanning signal of 10 V and an information signal of ±3 V as shown in FIG. 12. A smooth dynamic image was observed when the device was subjected to interlace driving at a frame frequency of 30 Hz.

This application claims priority from Japanese Patent Application No. 2004-299928 filed on Oct. 14, 2004, which is hereby incorporated by reference herein.

1. An organic electroluminescent device comprising:
a pair of electrodes; and
at least one organic compound layer including a light-emitting layer, interposed between the pair of electrodes,
wherein the light-emitting layer in the organic compound layer is composed of at least two kinds of compounds, and among the compounds, a compound having a highest concentration is a light-emitting material, which is an organic compound having an emission wavelength of a single body in a solid state shorter than an emission wavelength of the single body in a solution.

2. An organic electroluminescent device according to claim 1, wherein the light-emitting material is a metal complex.

3. An organic electroluminescent device according to claim 2, wherein a central metal of the metal complex is selected from the group consisting of Cu, Re, Ru, W, Ag, and Au.

4. An organic electroluminescent device according to claim 2, wherein the metal complex is a phosphorescent metal complex.

5. An organic electroluminescent device according to claim 1, wherein the organic electroluminescent device is an electroluminescent device in which the light-emitting layer emits light when a voltage is applied between the pair of electrodes.

6. A display apparatus comprising an organic electroluminescent device according to claim 1.

7. An active matrix substrate comprising:
an organic electroluminescent device according to claim 1, and a driving means for driving the organic electroluminescent device.

8. A display comprising an active matrix substrate according to claim 7.
